(19) United States
(12) Patent Application Publication
(10) Pub. No.: US 2010/0079164 A1
(43) Pub. Date: Apr. 1, 2010

(54) Systems and Methods for Improving the PN Ratio of a Logic Gate by Adding a Non-Switching Transistor

(76) Inventor: Fumihiro Kono, Yokohama (JP)

Correspondence Address: LAW OFFICES OF MARK L. BERRIER, 3811 BEE CAVES ROAD, SUITE 204, AUSTIN, TX, 78746, US

(21) Appl. No.: 12/243,140

(22) Filed: Oct. 1, 2008

(51) Int. Cl. H03K 19/003; H03K 19/173

(52) U.S. Cl. 326/9; 326/34; 326/47

(57) ABSTRACT

Systems and methods for improving a PN ratio of a logic gate by adding a non-switching transistor. In one embodiment, the logic gate includes a plurality of PMOS switching transistors and a plurality of NMOS switching transistors that are switched on and off by received input signals. The PMOS and NMOS switching transistors are interconnected to perform a logic operation on the input signals and produce a corresponding output signal. The non-switching transistor is inserted in the circuit to improve the ratio of PMOS and NMOS transistors between the power nodes of the logic gate. The non-switching transistor is either a PMOS transistor or an NMOS transistor as needed to make the PN ratio closer to 1. The non-switching transistor is biased to keep it switched on and does not affect the logic functions of the gate.

### BACKGROUND

1. Field of the Invention

The invention relates generally to integrated circuits, and more particularly to systems for increasing the reliability of logic gates.

2. Related Art

There is a continuing demand in the area of the design and manufacture of integrated circuits for increased computational power, improved reliability, and reduced cost. These goals are achieved in various ways, such as by improving the physical characteristics of the devices. For example, computational power may be increased by developing components that can operate at higher clock speeds than previous components. Device reliability may be increased by using components that operate properly in the presence of higher noise levels. Manufacturing costs can be reduced by increasing yields. Many techniques are used to meet these demands.

Conventionally, increased computational power may be achieved by increasing the speed and density of logic components. Unfortunately, increased speed and reduced size in these logic components typically also results in a greater sensitivity to noise. This sensitivity makes it more likely that component defects and manufacturing variations will cause greater numbers of logic components (and the IC's in which they are used) to fail. Some of these failures can be addressed with improvements in technology, but it would be desirable to be able to reduce the number of failures using existing technologies.

When the functional design of a digital device is being developed, logic gates provide the basic building blocks from which the device is constructed. Logic gates themselves are abstractions of groups of smaller components such as transistors that are connected to provide the functions of the logic gates. Different combinations of components and different types of components can be used to build the various different logic gates.

The selection of particular groups and types of components that are used to construct a logic gate may depend on a number of factors, such as the type of manufacturing technologies that are available, or the conditions under which the components will operate. Particular choices of components can affect the performance and reliability of the entire device.

For example, the choice of components affects the PN ratio of the logic gate. The PN ratio is the ratio of p-type transistors to n-type transistors through which current must flow in the logic gate. The PN ratio can shift the voltage at which a logic gate's transistors conduct current, potentially making the gate more susceptible to noise and thereby reducing its reliability. As a result, the clock speed, feature size, or characteristics may be adversely limited. In conventional schemes, the PN ratio typically is not a design criterion.

It would therefore be desirable to provide systems and methods to improve the PN ratios of logic gates and thereby improve the performance and reliability of the logic gates.

### SUMMARY OF THE INVENTION

One or more of the problems outlined above may be solved by the various embodiments of the invention. Broadly speaking, the invention includes systems and methods for improving the reliability of logic gates by improving the PN ratios of the gates. This is achieved by introducing one or more non-switching transistors into the designs of the gates.

In one embodiment, a logic gate includes a plurality of PMOS switching transistors and a plurality of NMOS switching transistors that are switched on and off by received input signals. The PMOS and NMOS switching transistors are interconnected to perform a logic operation on the input signals and produce a corresponding output signal. The non-switching transistor is inserted in the circuit to improve the ratio of PMOS and NMOS transistors between the power nodes of the logic gate. The non-switching transistor is either a PMOS transistor or an NMOS transistor as needed to make the PN ratio closer to 1. The non-switching transistor is biased to keep it switched on, and this transistor does not affect the logic functions of the gate.

One exemplary embodiment is a 4-input NAND gate. The gate includes four NMOS transistors that are coupled in series between an output of the gate and a ground node. The gate also includes four PMOS transistors that are coupled in parallel between the output of the gate and a PMOS non-switching transistor. The non-switching transistor is coupled between the PMOS switching transistors and a positive voltage node. Each of the four inputs to the NAND gate is connected to the gate of one of the PMOS transistors and also to the gate of one of the NMOS transistors. The gate of the non-switching transistor is connected to the ground node to keep it switched on. The addition of the PMOS non-switching transistor decreases the PN ratio of the gate to 2 (as compared to a PN ratio of 4 for the comparable conventional 4-input NAND gate).

Another exemplary embodiment is a 3-input NOR gate. The gate includes three PMOS transistors that are coupled in series between an output of the gate and a positive voltage node. The gate also includes three NMOS transistors that are coupled in parallel between the output of the gate and an NMOS non-switching transistor. The non-switching transistor is coupled between the NMOS switching transistors and a ground node. Each of the three inputs to the NOR gate is connected to the gate of one of the PMOS transistors and also to the gate of one of the NMOS transistors. The gate of the non-switching transistor is connected to the positive voltage node to keep it switched on. The addition of the NMOS non-switching transistor increases the PN ratio of the gate to 0.66 (as compared to a PN ratio of 0.33 for the comparable conventional 3-input NOR gate).

The various embodiments of the present invention may provide a number of advantages over the prior art. In particular, the embodiments of the present invention drive the PN ratio of the respective logic gates toward 1 and thereby drive the logic thresholds of the gates toward Vdd/2, which makes them less susceptible to noise than comparable conventional logic gates. This makes the present logic gates more reliable than the comparable conventional gates and thereby increases the yield of devices using the present gates.

### BRIEF DESCRIPTION OF THE DRAWINGS

Other objects and advantages of the invention may become apparent upon reading the following detailed description and upon reference to the accompanying drawings.

FIG. 1A is an illustration of the effect of a PN ratio on the output voltage of an exemplary logic gate.

FIG. 1B is an illustration of the effect of the PN ratio of an exemplary logic gate on the logic threshold associated with the gate.

FIG. 2 is a schematic diagram of a conventional 4-input NAND gate.

FIG. 3 is a schematic diagram of a modified 4-input NAND gate in accordance with one embodiment.

FIG. 4A is a schematic diagram of a conventional 3-input NOR gate.

FIG. 4B is a schematic of a modified 3-input NOR gate in accordance with one embodiment.

FIG. 5 is a flowchart illustrating a method in accordance with one embodiment.

While the invention is subject to various modifications and alternative forms, specific embodiments thereof are shown by way of example in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF EXEMPLARY EMBODIMENTS

One or more embodiments of the invention are described below. It should be noted that these and any other embodiments described below are exemplary and are intended to be illustrative of the invention rather than limiting.

Broadly speaking, the invention includes systems and methods for improving the design of logic gates that are used in integrated circuits. More particularly, the reliability of the logic gates is improved by introducing non-switching “dummy” transistors to the logic gates in order to improve the PN ratios of the logic gates and thereby reduce the susceptibility of the logic gates to noise.

Before describing the exemplary embodiments of the invention in detail, it will be helpful to introduce the PN ratio and its effect on conventional circuitry configurations.

The PN ratio of a logic gate, as used in the discussion below, is a ratio of the numbers of transistors of different types that are serially interconnected between the positive and ground rails of the logic gate. More specifically, the PN ratio is N/P, where the logic gate has a number P of P-type transistors and a number N of N-type transistors that are connected between the voltage rails.

It should be noted that the logic gate itself does not typically include voltage rails, but has power nodes that are connected to the voltage rails of the system in which the gate is installed. Accordingly, references herein to the positive and ground rails can be construed alternately as the rails themselves or as the power nodes of the logic gate which are configured to be coupled to the respective rails.

While it may appear that the PN ratio should be equal to P/N, the term is conventionally used to refer to the value N/P. This may be a result of the fact that the ratio of P-type transistors to N-type transistors that is usually considered to be ideal is 1:1. Thus, the ideal value of the PN ratio, whether P/N or N/P, is 1.

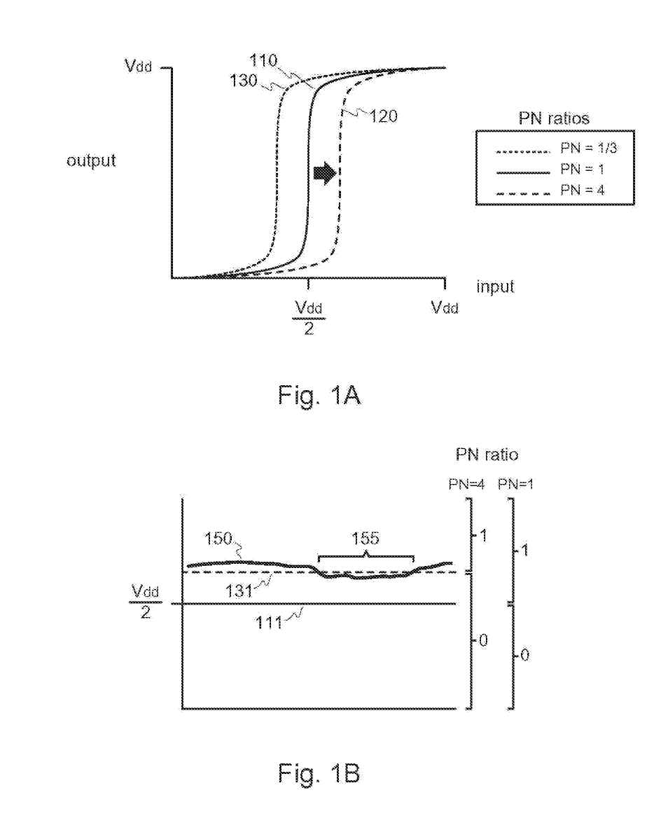

FIG. 1A is an illustration of the effect of an exemplary logic gate's PN ratio on the gate's output voltage. This plot shows the relationship between the gate's input and its output. Ideally, the output of the logic gate will be binary —either Vdd or 0. In other words, the gate establishes a logic threshold of Vdd/2, below which the gate's output is 0 and above which the output is 1.

In reality, the logic gate's output will be an approximation of this ideal step function. The output will be near 0 (rising gradually) when the input is less than Vdd/2, it will rise sharply at approximately Vdd/2, and it will be near Vdd (gradually increasing) when the input is greater than Vdd/2. This is most closely approximated when the logic gate's PN ratio has a target value of 1. As the PN ratio moves away from the target value, the center of the curve (the approximately vertical portion) shifts away from Vdd/2.

As illustrated in FIG. 1A, solid curve 110 represents a PN ratio of 1. This curve has its vertical portion centered about Vdd/2. When the PN ratio is greater than 1, the curve shifts to the right. Dashed curve 120 represents a PN ratio of 4. When the PN ratio is less than 1, the curve shifts to the left. Dotted curve 130 represents a PN ratio of 1/3. As the PN ratio increases and the curve shifts to the right, the logic threshold (above which a signal must rise in order to be 1) increases. As the PN ratio decreases and the curve shifts to the left, the logic threshold (above which a signal must rise in order to be 1) decreases.

FIG. 1B is a diagram illustrating one of the problems that arises from the effect of the PN ratio on logic thresholds. Exemplary signal 150 has a signal level that is greater than Vdd/2 and is intended to be interpreted as 1. Signal 150 is depicted as a slightly-varying (non-constant) signal to illustrate noise in the signal. It should be noted that, despite the noise, signal 150 never falls below Vdd/2.

FIG. 1B includes a solid horizontal line at Vdd/2 to show the threshold above which the logic gate should interpret a signal as a 1 (and below which the signal should be interpreted as a 0). In actuality, this is the threshold when the PN ratio of the logic gate is 1. As noted above, when the PN ratio is greater than 1, the threshold is greater than Vdd/2. This is illustrated by horizontal dashed line 131, which represents a PN ratio of 4. It can be seen that when the PN ratio is 4, the signal level of signal 150 drops below the logic threshold in region 155. As a result, the noise that causes signal 150 to drop below threshold 131 causes the signal to be interpreted as 0 in this region. By changing the PN ratio of the logic gate so that it is closer to 1, the logic threshold will be driven closer to Vdd/2, and the gate will be less susceptible to errors.

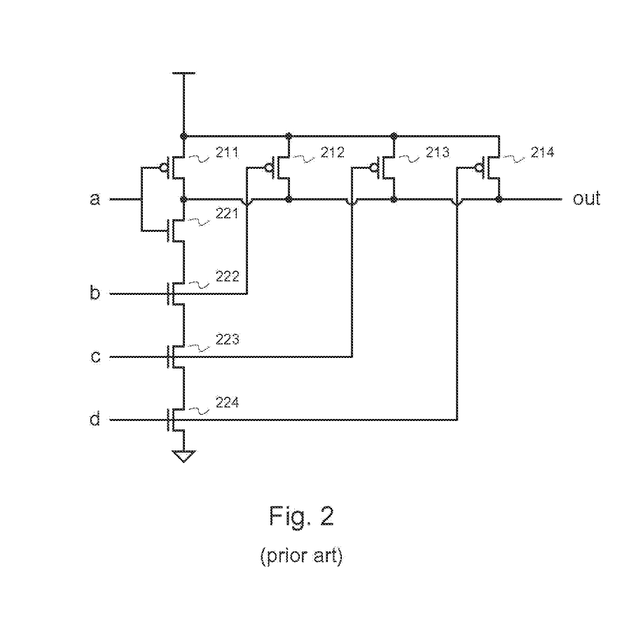

FIG. 2 is a schematic illustrating an exemplary, conventionally configured 4-input NAND gate (which may be referred to herein as a 4NAND gate). This 4NAND gate comprises four PMOS and four NMOS transistors. All of these transistors are switching transistors. Each of the inputs to the logic gate controls the switching of one of the PMOS transistors and one of the NMOS transistors.

The four PMOS transistors (211-214) are connected in parallel between the source (positive voltage) rail and the output. The four NMOS transistors (221-214) are connected in series between the output and the sink (ground) rail. There are therefore four rail-to-rail paths. Each of these paths traverses one of PMOS transistors 211-214 and all four NMOS transistors 221-224. Thus, the PN ratio of each path, and the PN ratio of the logic gate, is 4. As a result, the logic threshold of this device will likely be significantly greater than Vdd/2, and the gate may therefore be more susceptible to errors.

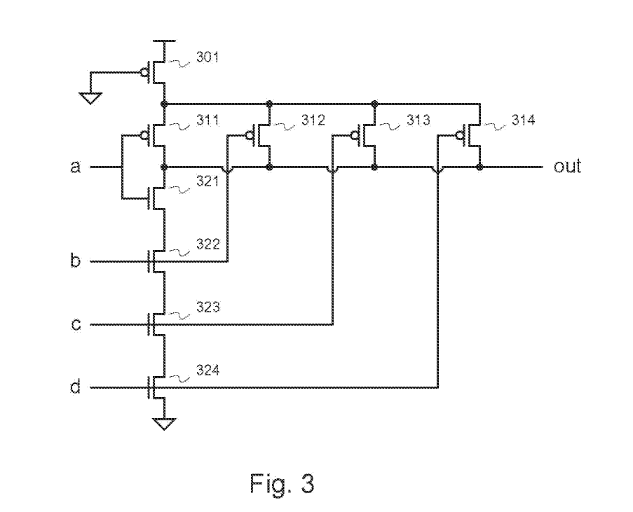

The PN ratio of the 4NAND gate illustrated in FIG. 2 can be improved by adding a PMOS transistor in series with the other transistors (so that each possible current path between the voltage rails traverses two PMOS transistors and four NMOS transistors). This is illustrated in FIG. 3.

FIG. 3 is a schematic of a 4-input NAND gate having a modified structure in accordance with one embodiment. The eight switching transistors (311-314, 321-324) are connected in the same manner as transistors 211-214 and 221-224 in the schematic of FIG. 2. However, an additional transistor (301) has been incorporated in this modified gate. A single, non-switching PMOS transistor 301 is connected between the switching PMOS transistors 311-314 and the source rail. The gate of transistor 301 is tied to the sink rail so that the transistor is always switched on. By placing non-switching transistor 301 in each of the possible rail-to-rail paths, each path between the source and sink rails traverses two PMOS transistors and four NMOS transistors. The resulting PN ratio is 2, a reduction from the previous ratio of 4. While this modification of the 4NAND gate will not decrease the logic threshold of the gate to Vdd/2 (see FIGS. 1A and 1B), it will be driven closer to this level, and the logic gate will be less susceptible to errors.

It should be noted that that the term “non-switching transistor,” as used herein, refers to a transistor that, although physically capable of switching, has an essentially constant voltage applied to its gate so that the transistor is always switched on. As a result, the non-switching transistor does not prevent current from flowing therethrough and does not affect the logical operations of the gate in which it is used. The non-switching transistor only alters the PN ratio of the logic gate. Conversely, “switching transistors” is used in the description to refer to those transistors that are controlled to switch on and off, thereby implementing the logical operations of the logic gate.

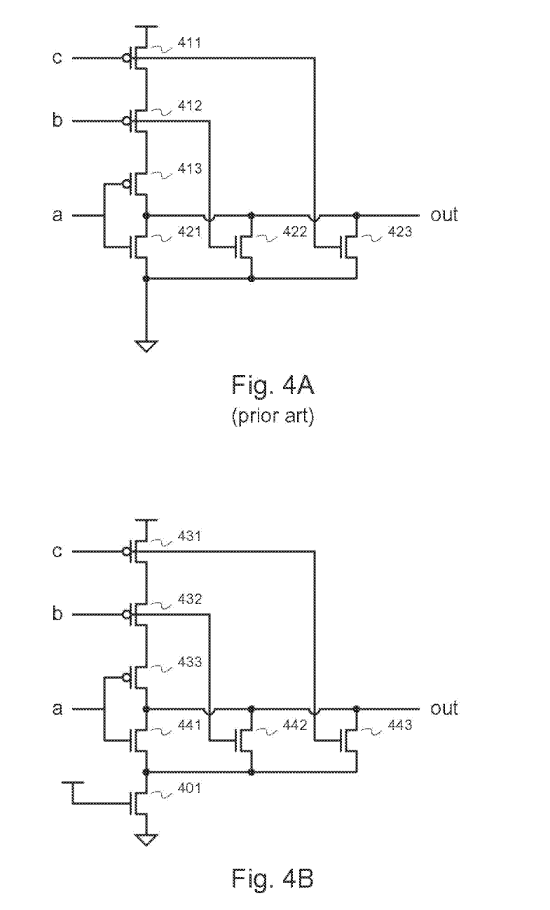

The foregoing description of a 4-input NAND gate incorporating an additional, non-switching transistor is intended to be exemplary. The improvement in PN ratio that is achieved by adding the non-switching transistor can be provided in other types of logic gates as well. FIGS. 4A and 4B illustrate the implementation of the non-switching transistor and the corresponding PN ratio improvement in a 3-input NOR gate. The improvement in the 3-input NOR gate is an increase from 1/3 to 2/3 as noted above, the PN ratio is improved by driving it closer to 1.

FIGS. 4A and 4B illustrate a conventional and an updated 3-input NOR gate, respectively. The additional non-switching transistor in the updated gate is of a different type and is placed in a different position than in the modified 4-input NAND gate of FIG. 3.

FIG. 4A is a schematic diagram illustrating an exemplary, conventionally configured 3-input NOR (“3NOR”) gate. This 3NOR gate comprises three PMOS and three NMOS transistors. The PMOS transistors (411-413) are connected in series between the source rail and the output of the logic gate. The NMOS transistors (421-423) are connected in parallel between the output of the gate and the sink rail. All of these transistors are switching transistors. The set 411-413 and set 421-423 are connected in series. It can be seen in FIG. 4A that each of the three paths between the source rail and the sink rail consists of one of NMOS transistors 411-413 and all three PMOS transistors 421-423. The PN ratio of the 3NOR gate is therefore 1/3.

FIG. 4B is a schematic of a modified 3-input NOR gate in accordance with one embodiment. The switching transistors (431-433, 442-443) in this embodiment are connected in the same manner as transistors 411-413 and 421-423 in the schematic of FIG. 4A. However, in the embodiment of FIG. 4B, an additional, non-switching NMOS transistor (401) has been incorporated. Vdd is applied to the gate of transistor 401 so that this transistor is always switched on. Non-switching transistor 401 is connected between the switching PMOS transistors (441-443) and the sink (ground) rail. Consequently, each of the possible rail-to-rail paths includes three PMOS transistors and 2 NMOS transistors. The resulting PN ratio for the gate is 2/3, which is closer to 1 than FIG. 4A's PN ratio of 1/3. The logic threshold for the device of FIG. 4B is therefore closer to Vdd/2 than is the logic threshold of the device of FIG. 4A.

It can be seen that, in the examples described above, the non-switching transistor in each case is inserted between the switching transistors of the opposite type and the voltage rail to which these transistors were previously connected. In the embodiment of FIG. 3, the non-switching transistor is a PMOS transistor that is inserted between the NMOS switching transistors and the positive voltage rail. In the embodiment of FIG. 4B, the non-switching transistor is an NMOS transistor that is inserted between the PMOS switching transistors and the ground rail. The specific positioning of the non-switching transistor in each of these embodiments is preferred, but is not required in alternative embodiments.

It should also be noted that that, although the exemplary embodiments of FIGS. 3 and 4B add only one non-switching transistor to the corresponding conventional designs, alternative embodiments may add more than one non-switching transistor. For example, if the logic gate that is being modified has a higher number of inputs, its PN ratio may be even farther from 1 than in the examples above (e.g., a 6-input NAND gate may have a PN ratio of 6). In this case, it may be desirable to include additional non-switching transistors in order to further improve the PN ratio. For instance, adding one non-switching transistor to a 6-input NAND gate may decrease the PN ratio from 6 to 3, while adding two non-switching transistors may decrease the PN ratio from 6 to 2.

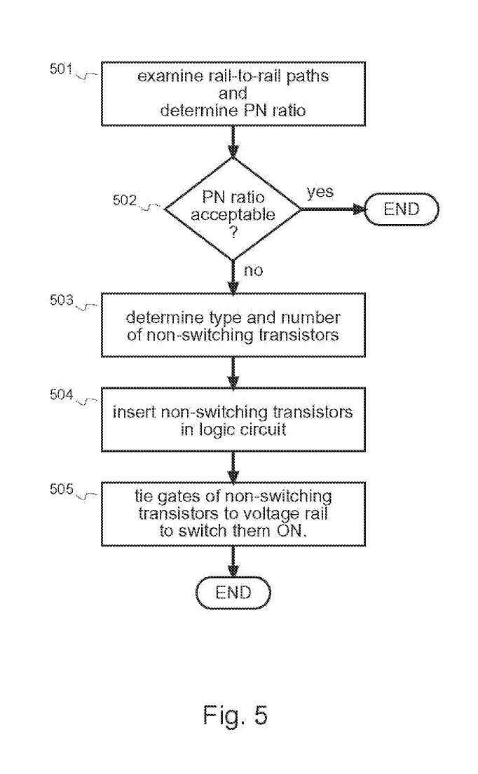

FIG. 5 is a flowchart illustrating a method for modifying the design of a logic gate to improve the gate's PN ratio in accordance with one embodiment. As shown in this figure, the PN ratio of the conventional design is first determined by examining the rail-to-rail paths through the gate's transistors (Block 501). If the paths (and, as a result, the circuit) have acceptable PN ratios, there is no need to proceed, so the method is terminated (Block 502). Otherwise, the type and number of non-switching transistors to be added are determined (Block 503). If there are more PMOS transistors, an NMOS transistor will be added. If there are more NMOS transistors, a PMOS transistor will be added. The non-switching transistor (or transistors) is then inserted into the circuit (block 504). Preferably, the non-switching transistor is inserted between the switching transistors of the opposite type and the voltage rail to which these transistors were conventionally connected. Finally, the gate of the non-switching transistor is tied to one of the voltage rails so that it is switched on (Block 505). If the non-switching transistor is a PMOS transistor, its gate will be tied to the ground rail. If the non-switching transistor is an NMOS transistor, its gate will be tied to the positive rail.

It should be noted that the addition of the non-switching transistor (which does not alter the logic operation of the device) requires a small amount of additional space on the IC. Typically, a logic gate is manufactured by forming a grid consisting of strips of p-type and n-type semiconductor materials interconnected by metal traces. In the case of the 4-input NAND gate discussed above, the additional transistor of the modified gate increases the space requirement for the circuit layout by about 20%. While the increased space makes the modified logic gate more costly than the conventional gate, the modified gate has a logic threshold that is less skewed from the midpoint between ground and Vdd, which results in fewer errors and therefore increases the yield of the devices in which the modified gate is used.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

What is claimed is:

1. An improvement to a logic gate, wherein the logic gate includes a plurality of PMOS switching transistors and a plurality of NMOS switching transistors interconnected to perform a logic operation on a plurality of inputs to produce an output, wherein the improvement comprises:
at least one non-switching transistor interconnected with the plurality of PMOS switching transistors and the plurality of NMOS switching transistors;
wherein the logic gate has a first PN ratio excluding the non-switching transistor and a second PN ratio including the non-switching transistor, and wherein the second PN ratio is between 1 and the first PN ratio.

2. A logic gate comprising:
a first number of PMOS switching transistors;
a second number of NMOS switching transistors; and
a third number of non-switching transistors;
wherein each of the switching transistors is configured to be alternately switched on and off by a corresponding input signal;
wherein each of the non-switching transistors is configured to remain switched on;
wherein the PMOS and NMOS switching transistors are interconnected to form a logic gate;
wherein the non-switching transistors are connected to the switching transistors to form at least one path between a positive voltage node and a ground node;
wherein the at least one path has a first PN ratio of NMOS transistors to PMOS transistors excluding the non-switching transistors, and a second PN ratio of NMOS transistors to PMOS transistors including the non-switching transistors; and
wherein the second PN ratio is between 1 and the first PN ratio.

3. The logic gate of claim 2, wherein each of the switching transistors is configured to receive an input signal, wherein the switching transistor is configured to alternately switch on and of in dependence upon the received input signal.

4. The logic gate of claim 3, wherein each of the input signals is provided to one of the PMOS switching transistors and one of the NMOS switching transistors.

5. The logic gate of claim 2, wherein each of the non-switching transistors is configured to remain switched on.

6. The logic gate of claim 5, wherein the gate of each non-switching transistor is connected to one of: the positive voltage node; and the ground node.

7. The logic gate of claim 2, wherein the PMOS switching transistors are connected in parallel between an output of the logic gate and the non-switching transistor, the non-switching transistor is a PMOS non-switching transistor connected between the PMOS switching transistors and the positive voltage node, and the NMOS switching transistors are connected in series between the output and the ground node.

8. The logic gate of claim 2, wherein the NMOS switching transistors are connected in parallel between an output of the logic gate and the non-switching transistor, the non-switching transistor is an NMOS non-switching transistor connected between the NMOS switching transistors and the ground node, and the PMOS switching transistors are connected in series between the output and the positive voltage node.

9. A logic gate comprising:
a first number of switching transistors of a first type;
a second number of switching transistors of a second type; and
a non-switching transistor;
wherein the first number of switching transistors of the first type are connected in series between an output and a first voltage node;
wherein the second number of switching transistors of the second type are connected in parallel between the output and the non-switching transistor;
wherein the non-switching transistor is connected between the second number of switching transistors of the second type and a second voltage node;
wherein the logic gate has a first PN ratio of NMOS transistors to PMOS transistors excluding the non-switching transistor, and a second PN ratio of NMOS transistors to PMOS transistors including the non-switching transistor; and
wherein the second PN ratio is between 1 and the first PN ratio.

10. The logic gate of claim 9, wherein the first type is NMOS and the first voltage node is a ground node, wherein the second type is PMOS and the second voltage node is a positive voltage node, and wherein the non-switching transistor is a PMOS transistor.

11. The logic gate of claim 10, wherein the first number is 4, the second number is 4, the first PN ratio is 4 and the second PN ratio is 2.

12. The logic gate of claim 9, wherein the first type is PMOS and the first voltage node is a positive voltage node, wherein the second type is NMOS and the second voltage node is a ground node, and wherein the non-switching transistor is a NMOS transistor.

13. The logic gate of claim 12, wherein the first number is 3, the second number is 3, the first PN ratio is 1/3 and the second PN ratio is 2/3.

14. The logic gate of claim 9, further comprising a plurality of inputs, wherein each input is connected to the gate of one of the transistors of the first type and one of the transistors of the second type.

15. The logic gate of claim 14, wherein the gate of the non-switching transistor is connected to the first voltage node.
